(19) United States
(12) Patent Application Publication
(10) Pub. No.: US 2025/0112195 A1
(43) Pub. Date: Apr. 3, 2025

(54) SEMICONDUCTOR DEVICE ARRANGEMENT STRUCTURE AND METHOD OF MANUFACTURING THE SAME

(71) Applicant: EPISTAR CORPORATION, Hsinchu (TW)

(72) Inventors: Wen-Chien WU, Hsinchu (TW); Wei-Shan HU, Hsinchu City (TW); Ching-Tai CHENG, Hsinchu (TW)

(21) Appl. No.: 18/903,920

(22) Filed: Oct. 1, 2024

(30) Foreign Application Priority Data
Oct. 2, 2023 (TW) 112137680

(51) Int. Cl. H01L 23/00; H01L 23/12; H01L 25/075

(52) U.S. Cl. CPC H01L 24/29; H01L 24/32; H01L 24/83; H01L 24/97; H01L 25/0753; H01L 23/12; H01L 2224/29019; H01L 2224/29191; H01L 2224/32225; H01L 2224/83224; H01L 2224/95001

(57) ABSTRACT

A semiconductor device arrangement structure includes a carrier, semiconductor devices, and an adhesive layer. The semiconductor devices are separately disposed on the carrier, and each of the semiconductor devices includes an electrode. The adhesive layer is disposed between the carrier and the semiconductor devices, and the semiconductor devices are attached to the adhesive layer which is a continuous distributed single-layered structure. The adhesive layer includes unselected regions and a selected region, wherein the unselected regions are covered by the semiconductor devices respectively, and the selected region is not covered by the semiconductor devices. The adhesive layer further includes an indentation disposed on a surface of the selected region, and in a cross-sectional view or a top view, the contour of the indentation is a scaled copy of a contour of and the electrode, and the indentation has a depth less than that of the electrode.

### RELATED APPLICATIONS

This application claims priority to the benefit of Taiwan Patent Application Number 112137680 filed on Oct. 2, 2023, the contents of which are hereby incorporated by reference herein in their entirety.

### Technical Field

The present disclosure relates to a semiconductor device arrangement structure, and more particularly, to a semiconductor device arrangement structure and its manufacturing method in which semiconductor devices are adhered to a carrier.

### Description of Background Art

Semiconductor optoelectronic devices, such as light-emitting diode (LED), have advantages of low power consumption, low generated heat, long working life, shockproof, small in size, rapid response and good optoelectronic properties (e.g., stable luminous wavelength). Therefore, they are widely applied to electronic equipment, such as household appliances, equipment indicators, and displays.

In order to manufacture different electronic devices, a large number of light-emitting diodes needs to be transferred between different substrates. The steps usually include transferring plural light-emitting diodes from a growth substrate to a temporary substrate and fixing the plural light-emitting diodes on the temporary substrate via adhesive layer thereon. After that, etching process is employed to remove the adhesive layer between adjacent light-emitting diodes, and after the etching process is performed, a portion of the adhesive layer still exists between the surface of the light-emitting diodes (e.g., the front surface of the electrode) and the temporary substrate. Subsequently, the light-emitting diodes may be transferred to a target substrate to make the back surfaces of the light-emitting diodes face the target substrate, while the front surfaces of the light-emitting diodes face away from the target substrate. After that, etching process is performed to remove the portions of the adhesive layer on the front surfaces of the light-emitting diodes to further expose the electrodes of the light-emitting diodes for subsequent external electrical connection.

During each one of the aforementioned etching processes, to remove the portions of the adhesive layer between the adjacent light-emitting diodes or on the front surface of each light-emitting diode, the etching processes usually consume long etching periods, and the generated heat during the etching processes may also cause some of the light-emitting diodes skew in a direction vertical to the surface of the substrate or shift in a direction parallel to the surface of the substrate. It may result in time-consuming manufacturing process and low yield, but also detrimental to subsequent processes.

### SUMMARY OF THE APPLICATION

In view of this, embodiments of the present disclosure provide a semiconductor device arrangement structure and its manufacturing method to overcome the technical problems described in the background art.

According to an embodiment of the present disclosure, which provides a semiconductor device arrangement structure. It comprises a carrier, a plurality of semiconductor devices, and an adhesive layer. The plural semiconductor devices are separately disposed on the carrier, and each of the semiconductor devices has an electrode. The adhesive layer is disposed between the carrier and the semiconductor devices, and the plural semiconductor devices are attached on the adhesive layer. The adhesive layer is a single-layered structure which is continuously distributed and comprises a plurality of unselected regions and a selected region. The plural unselected regions are covered by the semiconductor devices one-on-one respectively, and the selected region is not covered by the semiconductor device. The adhesive layer further comprises an indentation disposed on a surface of the selected region of the adhesive layer. In a cross-sectional view, a contour of the indentation is a scaled copy of a contour of the electrode, and a depth of the indentation is less than a thickness of the electrode.

According to an embodiment of the present disclosure, a manufacturing method for semiconductor device arrangement is provided to comprise: providing a carrier, wherein the carrier is provided with an adhesive layer on a surface thereof, and the adhesive layer is a single-layered structure with the material of elastomer; attaching a semiconductor device on a selected region of the adhesive layer; providing a target substrate comprising a surface facing the semiconductor device and not contacting the semiconductor device; and energizing the selected region of the adhesive layer to make the semiconductor device separated from the adhesive layer and transferred to the surface of the target substrate. Wherein before energizing the selected region of the adhesive layer, the selected region of the adhesive layer is still attached on the carrier.

### BRIEF DESCRIPTION OF THE DRAWINGS

Aspects of the present disclosure are better understood from the following detailed description when read with the accompanying figures. Through the specific embodiments and the corresponding figures of the disclosure, the detail of the specific embodiments and the action principles of the present disclosure are thus better illustrated. In addition, for the sake of clarity, the features of each of the figures may not be drawn in accordance with practical scale. The size of some of the features in the figures may be deliberately scaled up or down, wherein:

FIG. 1 illustrates an aerial view and a partial enlarged view of a semiconductor device arrangement structure in accordance with an embodiment of the present disclosure;

FIG. 2 illustrates a cross-sectional view of the semiconductor device arrangement structure taken along cross-sectional line A-A′ of FIG. 1 in accordance with an embodiment of the present disclosure;

FIG. 3 illustrates an enlarged view of partial region R2 of FIG. 2 in accordance with an embodiment of the present disclosure;

FIG. 4 illustrates a partial enlarged view of the semiconductor device arrangement structure in accordance with another embodiment of the present disclosure;

FIG. 5 illustrates a partial enlarged view of the semiconductor device arrangement structure in accordance with another embodiment of the present disclosure;

FIG. 6 illustrates an aerial view of the semiconductor device arrangement structure in accordance with an embodiment of the present disclosure;

FIG. 7 illustrates a cross-sectional view of the semiconductor device arrangement structure taken along cross-sectional line B-B′ of FIG. 6 in accordance with of an embodiment of the present disclosure;

FIG. 8 illustrates an enlarged view of partial region R3 of FIG. 7 in accordance with an embodiment of the present disclosure;

FIG. 9 illustrates cross-sectional views of the semiconductor devices showing that the semiconductor devices are transferred from a first support substrate to a second support substrate in different manufacturing processes in accordance with an embodiment of the present disclosure;

FIG. 10 illustrates cross-sectional views of the semiconductor devices showing that the semiconductor devices are transferred from the second support substrate to a third support substrate in different manufacturing processes in accordance with an embodiment of the present disclosure; and

FIG. 11 illustrates cross-sectional views of the semiconductor devices showing that the plural semiconductor devices are transferred from the second support substrate to the third support substrate in different manufacturing processes in accordance with another embodiment of the present disclosure.

### DETAILED DESCRIPTION OF THE APPLICATION

Different embodiments of the present disclosure are described in detail in the following description. It should be understood that in the following detailed description, for purposes of explanation, numerous specific details and embodiments are set forth to provide a thorough understanding of the present disclosure. The elements and configurations described in the following detailed description are set forth to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

Further, spatially relative terms, such as “beneath,” “below,” “lower,” “over,” “above,” “upper” and the like, may be used herein for ease of description to describe one element or feature's relationship to another element(s) or feature(s) as illustrated in the figures. The spatially relative terms are intended to encompass different orientations of the semiconductor device in use or operation in addition to the orientation depicted in the figures. For example, if the semiconductor device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or manufacturing order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

In the description of the embodiments of the present disclosure, the terms “coupling” and “electric connection” may comprise any direct or indirect electric connection. For instance, if the document describes the first object is coupled to a second object, it means the first object may be directly electrically connected with the second object or indirectly electrically connected to the second object via other device or connecting means.

Although the present disclosure below is described through specific embodiments, the inventive principles may also be applied to other embodiments. In addition, in order not to obscure the spirit of the present invention, specific details may be omitted, and these omitted details fall within the scope of knowledge of those with ordinary skill in the art.

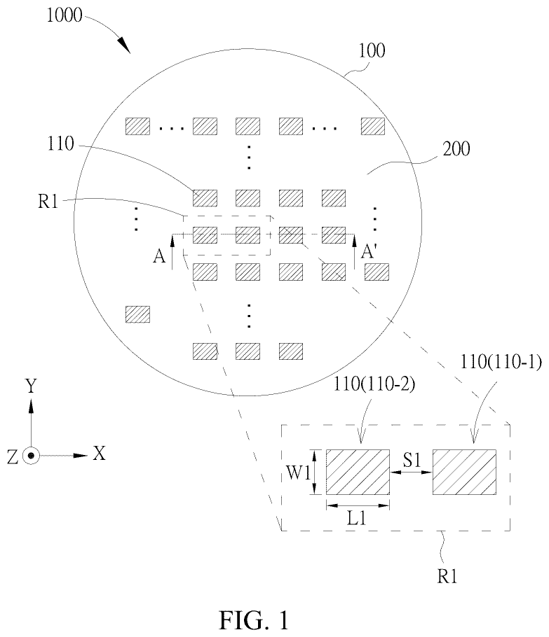

FIG. 1 illustrates an aerial view and a partial enlarged view of a semiconductor device arrangement structure in accordance with an embodiment of the present disclosure. As shown in FIG. 1, the semiconductor device arrangement structure 1000 comprises a carrier 100, an adhesive layer 200, and a plurality of semiconductor devices 110. The adhesive layer 200 is continuously distributed on a surface of the carrier 100 and disposed between the carrier 100 and the plurality of the semiconductor devices 110, so that the semiconductor devices 110 can be attached on the adhesive layer 200. The semiconductor devices 110 are separately disposed on the carrier 100 and arranged in a regular or irregular pattern.

According to an embodiment of the present disclosure, the carrier 100 supports the semiconductor devices 110 on the surface thereof, therefore the carrier 100 and the adhesive layer 200 may constitute a support substrate (or called second support substrate). According to an embodiment of the present disclosure, the carrier 100 may be made by non-epitaxial material and may be a non-growth substrate, e.g., a ceramic substrate, metallic substrate, glass substrate, thermal release tape, UV release tape, chemical release tape, heatproof tape, blue tape, or a tape having dynamic release layer (DRL). According to an embodiment of the present disclosure, the carrier 100 may be a glass substrate, a sapphire substrate, or a quartz substrate. The carrier 100 is a substrate that is penetrable for laser light or non-coherent light, so that the semiconductor device 110 may be separated from the carrier 100 by means of laser lift-off (LLO) process. According to an embodiment, when laser lift-off process is performed, if the adhesive layer is disposed on the front surface of the carrier 100, laser light may be incident into the carrier 100, irradiates the adhesive layer 200 and penetrates through the front surface of the carrier 100. The adhesive layer 200 can then be partially swollen under laser light irradiation to push the semiconductor device 110 to be separated from the carrier 100. In addition, the carrier 100 is electrically insulated from the semiconductor devices 110 so electric signals do not transmit between the carrier 100 and the semiconductor devices 110.

The semiconductor device 110 may comprise light-emitting device or non-light-emitting device. The light-emitting device may be a light-emitting diode or a laser diode, while the non-light-emitting device may be a transistor. The plural semiconductor devices 110 each may have different, the same, or similar structures or sizes. According to an embodiment, the semiconductor devices 110 each has a projected area ranged from 50 μm² to 5000 μm² in the Z axial direction. The adjacent semiconductor devices 110 are separated from each other, and a shortest distance defined between two adjacent semiconductor devices 110 arranged in the same row or in the same column is ranged from 1 μm to 50 μm.

Taking reference to the enlarged view of the partial region R1, two semiconductor devices 110 (e.g., the first semiconductor device 110-1 and the second semiconductor device 110-2) are adjacent to each other, and each of them has a length L1 and a width W1. The length L1 is greater than the width W1. The length L1 is ranged from 10 μm to 50 μm, and the width W1 is ranged from 5 μm to 30 μm. The shortest distance S1 defined between the first semiconductor device 110-1 and the second semiconductor device 110-2 is less than one of the widths W1 of the first and second semiconductor devices 110-1, 110-2. The shortest distance S1 is greater than one fifth of the width W1 of one of the first and second semiconductor devices 110-1, 110-2.

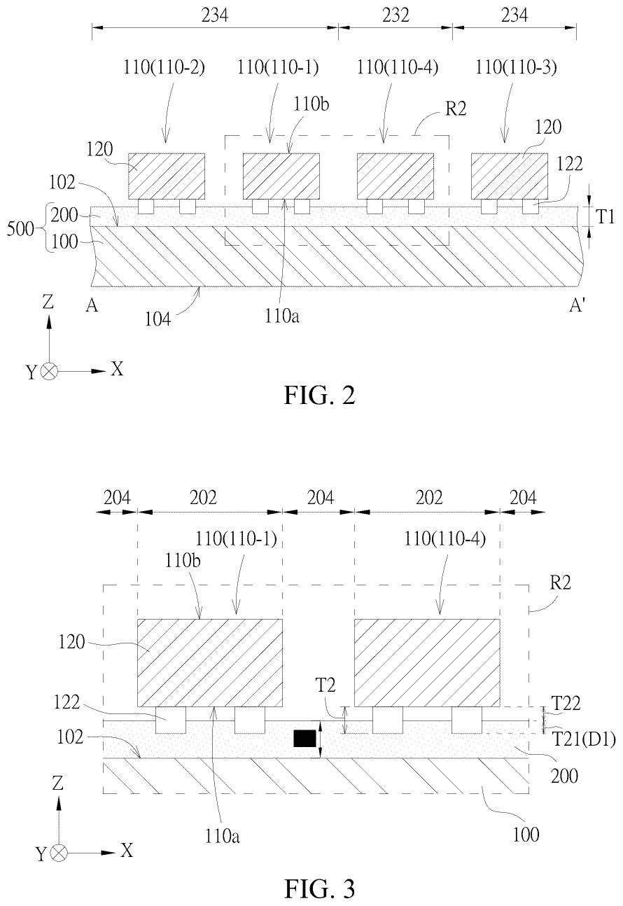

FIG. 2 illustrates a cross-sectional view of FIG. 1 taken along cross-sectional line A-A′ in accordance with an embodiment of the present disclosure. In the cross-sectional view, the carrier 100 has a front surface 102 and a back surface 104 opposite to the front surface 102. The adhesive layer 200 is disposed on the front surface 102 of the carrier 100, and it is a single-layered structure that is continuously distributed. The adhesive layer 200 is provided with an exposed surface (i.e., the region not covered by the semiconductor devices 110) having an even thickness T1, which maybe ranged, e.g., from 50 nm to 2 μm, and a thickness variation ratio defined by the thickness variance between any two points of the exposed surface of the adhesive layer 200 over the average thickness of the two points of the exposed surface of the adhesive layer 200 is less or equal to 15%. For instance, the thickness variation ratio can be obtained by the following formula:

$$\frac{\vert t 1 - t 2 \vert}{( t 1 + t 2 ) / 2} , \qquad ( 1 )$$

wherein t1 and t2 are the thicknesses of any two points of the exposed surface of the adhesive layer 200.

In addition, per the exposed surface of the adhesive layer 200, the adhesive layer 200 does not comprise any cutting trace. According to an embodiment, the adhesive layer 200 is a single-layered elastomer, which is non-fluid and have appropriate adhesion under the condition of normal temperature (e.g., 25° C.) and normal atmospheric pressure (e.g., 1 atm). Therefore, when other objects are disposed on the exposed surface of the adhesive layer 200, the object can be attached to the adhesive layer 200.

In the present disclosure, the “elastomer” indicates a polymer with elastic feature. The “elastic” or “elastomeric” indicate that when a pulling force exerted to a material, the total length of the material can be lengthened and has an elongated length, which is at least 160% of the original length of the material without rupture or break. When the exerted pulling force is released, the total length of the material may have a recovered length, which is at least 65% of the original length of the material. Therefore, the recovered length may be ranged from 103% to 120% of the original length or within any value between the aforementioned range. In addition, in each of the directions, after being subjected to an external force and the external force is released, the elastomer restores and the ratio of the recovered length of the elastomer to the original length of the elastomer is substantially the same. The adhesive layer 200 may comprise silicone or light debonding glue, such as UV light debonding glue.

The adhesive layer 200 comprises selected region 232 and unselected regions 234. The physical property and the chemical property of the selected region 232 and the unselected region 234 are substantially the same. That is, the adhesion, the light transmittance, the cross-linking degree, and the composition of the selected region 232 and the unselected region 234 are substantially the same. However, the so-called “selected region 232” refers to the region that will be energized by a stimulus (e.g., a light source or heat source) at a certain manufacturing process time point, while the unselected region 234 refers to the region that does not be energized by the stimulus source at the aforementioned manufacturing process time point. According to an embodiment, at a certain manufacturing process time point, the certain regions of the adhesive layer 200 may belong to unselected region 234, but at other manufacturing process time points, such regions may belong to selected region 232, depending on actual needs. The carrier 100 supports the semiconductor devices 110 disposed on the surface thereof, so the carrier 100 and the adhesive layer 200 jointly constitute the second support substrate 500.

The semiconductor device 110 is attached to the surface of the adhesive layer 200. The semiconductor device 110 comprises a first semiconductor device 110-1, a second semiconductor device 110-2, a third semiconductor device 110-3, and a fourth semiconductor device 110-4. The first, second, and third semiconductor devices 110-1, 110-2, 110-3 are attached to the unselected region 234 of the adhesive layer 200, while the fourth semiconductor device 110-4 is attached to the selected region 232 of the adhesive layer 200. According to an embodiment of the present disclosure, the semiconductor devices 110 disposed in the unselected regions 234, such as the first semiconductor device 110-1 through the third semiconductor device 110-3, may be called unselected semiconductor devices, while the semiconductor devices 110, such as the fourth semiconductor device 110-4, disposed in the selected region 232 may be called selected semiconductor devices. In the subsequent transferring process, the fourth semiconductor device 110-4 in the selected region 232 can be transferred to a target substrate, while the first semiconductor device 110-1 through the third semiconductor device 110-3 are remined on the original carrier 100. According to an embodiment, all of the unselected regions 234 at different manufacturing process time points become the selected region 232, so all of the semiconductor device 110 can be simultaneously or sequentially transferred to other target substrate. Depending on actual needs, these semiconductor devices 110 can be transferred to the same or different target substrates.

The front surface 110a of the semiconductor device 110 faces the adhesive layer 200, and the back surface 110b of the semiconductor device 110 faces away from the adhesive layer 200. Each of the semiconductor devices 110 comprises a device main body 120 and at least one electrode 122, e.g., two electrodes 122. The device main body 120 comprises semiconductor layers allowing the flowing of electrons or electric holes. The electrodes 122 face and attached to the adhesive layer 200, and a portion of the electrodes 122 each is inserted into the adhesive layer 200. The electrode 122 may comprise a single-layered structure or a multiple layer structure, and the electrode 122 comprises one material selected from a group constituted by chromium (Cr), nickel (Ni), titanium (Ti), platinum (Pt), palladium (Pd), silver (Ag), gold (Au), aluminum (Al), and copper (Cu).

According to an embodiment, the semiconductor device 110 is a light-emitting semiconductor device. The device main body 120 of the semiconductor device 110 comprises a semiconductor stack. The semiconductor stack comprises a plurality of concave sections that is disposed away from the carrier 100. The concave sections each have an opening with a diameter ranged from 1 μm to 4 μm and a depth ranged from 300 nm to 2 μm. The concave sections each have a duplicated shape and are distributed on the back surface 110b of the semiconductor device 110 (distributed along the X-Y plane). By means of arranging the concave sections, the luminous efficiency of the semiconductor device 110 can be enhanced and the contour of the light distribution curve can be adjusted. The device main body 120 of the semiconductor stack may be electrically connected to the electrode 122. The semiconductor stack comprises a first semiconductor layer, a light-emitting layer, and a second semiconductor layer in a sequence. The first semiconductor layer and the second semiconductor layer have different dopant with different electric conductivity types respectively, e.g., n-type dopant or p-type dopant, so that the first semiconductor layer and the second semiconductor layer can supply electrons and electric holes respectively.

The structures of the semiconductor devices 110 each are not limited to the structures shown in FIG. 2. According to an embodiment, each of the semiconductor devices 110 comprises a growth substrate (not shown in the figures) disposed on the back surface (upper surface) of the device main body 120 and a redistribution layer (RDL) disposed on the bottom layer of the device main body 120. The redistribution layer comprises interconnect, via, and bonding pad. The bonding pad may have a specific layout pattern, and in the subsequent manufacturing process, the bonding pad may be electrically connected with an external electric circuit. In addition, according to an embodiment, the semiconductor devices 110 each may comprise a fan-out package, so the device main body 120 comprises one semiconductor device and a molding material surrounding the semiconductor device.

FIG. 3 is an enlarged view of a partial region of FIG. 2 in accordance with an embodiment of the present disclosure. As shown in FIG. 3, in the partial region R2, each of the electrodes 122 of the semiconductor devise 122 has an average thickness T2, and the average thickness is ranged, e.g., from 200 nm to 2 μm. A portion of each of the electrodes 122 with a first thickness T21 (or called depth) is embedded into the adhesive layer 200. The first thickness T21 is ranged from 0.02 μm to 0.5 μm. Other portion of each of the electrode 122 with a second thickness T22 is exposed outside the adhesive layer 200, and the second thickness T22 is ranged from 0.04 μm to 1.55 μm.

The surface of the adhesive layer 200 comprises recess sections served for accommodating the electrodes 122. A first depth D1 of the recess section is equal to the thickness T21 (or called depth) of the electrode 122 embedded in the adhesive layer 200. The adhesive layer 200 may have covered portions 202 and exposed portions 204 that are alternately arranged. The covered portion 202 may be covered by the semiconductor device 110, while the exposed portion 204 is exposed from the semiconductor device 110. The physical feature and the chemical feature of the covered portion 202 and the exposed portion 204 are substantially the same. That is, the adhesion, the light transmittance, cross-linking degree, and the composition of the covered portion 202 and the exposed portion 204 are substantially the same. However, since the surface of the covered portion 202 comprises the recess sections served for accommodating the electrodes 122, the average thickness of the covered portion 202 may be slightly less or substantially equal to the average thickness of the exposed portion 204.

Taking the covered portion 202 and the exposed portion 204 of the first semiconductor device 110-1 as an example, the covered portion 202 and the exposed portion 204 are disposed on the unselected region of the adhesive layer 200. This corresponding covered portion 202 can be covered by the first semiconductor device 110-1 and have a first average thickness. In an aerial view, the corresponding covered portion 202 may be surrounded by the adjacent exposed portion 204, and the adjacent exposed portion 204 has a second average thickness. The ratio of the first average thickness of the aforementioned covered portion 202 to the second average thickness of the aforementioned exposed portion 204 is ranged from 0.96 to 1.00.

According to an embodiment, the adhesive layer 200 is silicone or UV light debonding glue. When the selected regions or the unselected regions of the adhesive layer 200 are irradiated by laser light with specific wavelength (e.g., wavelength 193 nm), the irradiated adhesive layer 200 can be heated and swollen, e.g., swell 10% to 30% in the longitudinal direction, such swelling can decrease the volume of the recess section on the surface of the adhesive layer 200 and reduce the contact area between the electrode 122 of the corresponding semiconductor device 110 and the adhesive layer 200, thus the attachment force between them is reduced. On the other hand, since the irradiated adhesion layer 200 is rapidly heated in a very short time period (e.g., less than 2 seconds), the rapidly swollen adhesive layer 200 can generate pushing force toward the semiconductor device 110 accordingly, e.g., a pushing force greater than or equal to 25 gram-force, to make the semiconductor device 110 separated from the adhesive layer 200. The value of the pushing force value is merely exemplified and the actual value may differ due to the layer energy and the material of the adhesive layer 200. Therefore, the pushing force value may be further adjusted in accordance with actual needs.

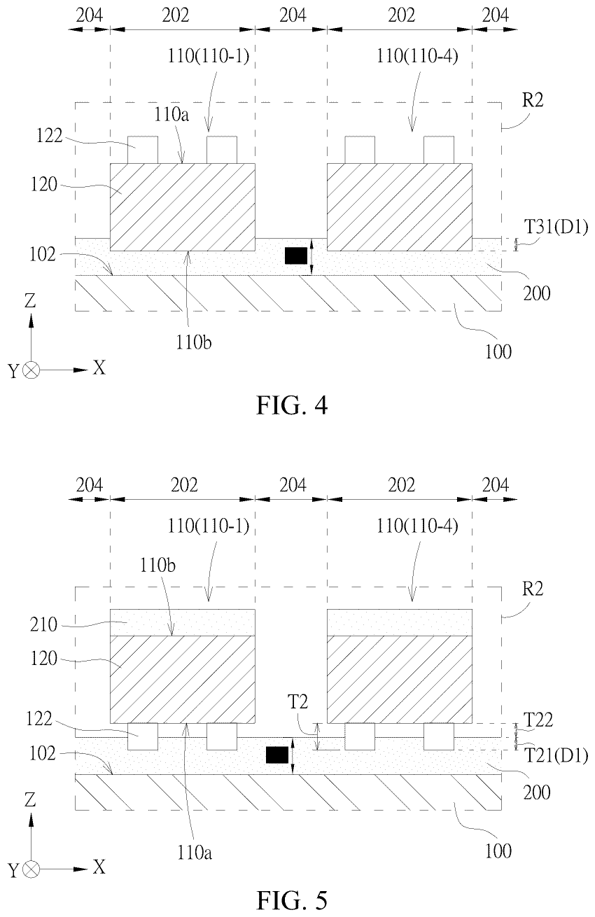

FIG. 4 is an enlarged view of a partial region of FIG. 2 in accordance with another embodiment of the present disclosure. The structure shown in FIG. 4 is similar to the structure shown in FIG. 3. The primary difference is that the back surface 110b of the semiconductor device 110 faces the adhesive layer 200, so a portion of the device main body 120 is embedded into the adhesive layer 200 and the thickness (or called depth) of such portion is ranged from 0.02 μm to 0.5 μm, while the front surface 110a of the semiconductor device 110 (comprising the electrodes 122) faces away from the adhesive layer 200. The surface of the adhesive layer 200 comprises the recess sections accommodating the device main body 120 of the semiconductor device 110. The first depth D1 of the recess section is equal to the thickness T31 (or called depth) of the portion of the device main body 120 embedded in the adhesive layer 200.

FIG. 5 is an enlarged view of the partial region of FIG. 2 in accordance with another embodiment of the present disclosure. The structure shown in FIG. 5 is similar to the structure shown in FIG. 3. The primary difference is that the back surface 110b of the semiconductor device 110 is covered by an adhesive portion 210. According to different embodiments, the composition of the adhesive portion 210 comprises cross-linked cured polymer, such as polyimide (PI), polyepoxide (EPO), polybenzoxazole (PBO), polysiloxane, Cyclic Olefin Polymer (COP), and benzocyclobutane (BCB).

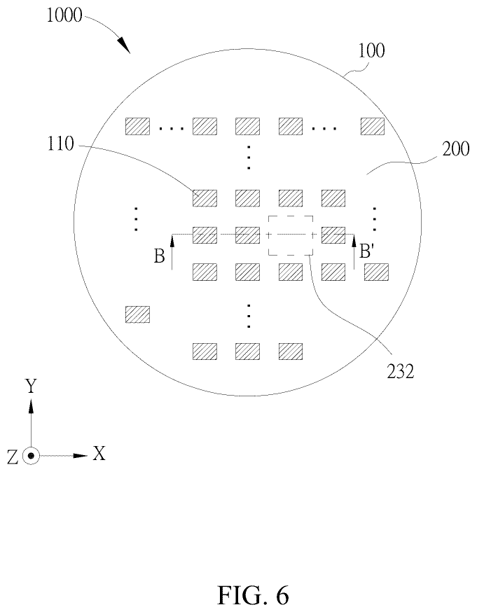

FIG. 6 is an aerial view of the semiconductor device arrangement structure in accordance with an embedment of the present disclosure. As shown in FIG. 6, the structure shown in FIG. 6 is similar to the structure shown in FIG. 1. The primary difference is that the original semiconductor device 110 disposed on the selected region 232 of the adhesive layer 200 is transferred to another support substrate (or called target substrate), so that the selected region 232 of the adhesive layer 200 is exposed.

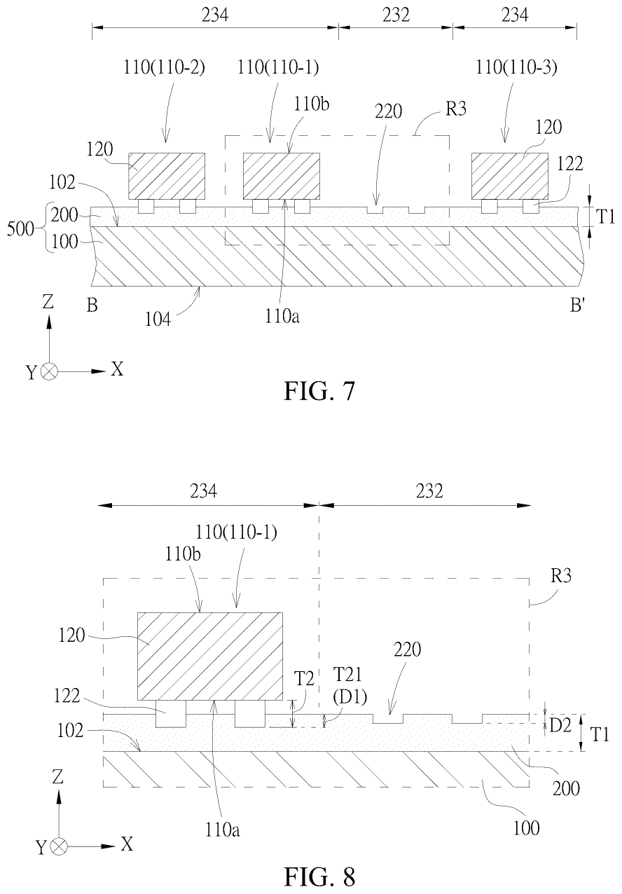

FIG. 7 is a cross-sectional view taken along cross-sectional line B-B′ of FIG. 6 in accordance with an embodiment of the present disclosure. Taking reference to FIG. 2 and FIG. 7 simultaneously, the structure shown in FIG. 7 is similar to the structure shown in FIG. 2. The primary difference is that the original fourth semiconductor device 110-4 on the selected region 232 of the adhesive layer 200 is transferred to another target substrate, so that the selected region 232 of the adhesive layer 200 is exposed. At this time, the surface of the selected region 232 comprises an indentation 220. In one embodiment, the indentation 220 is caused by and is corresponding to the electrodes 122.

FIG. 8 is an enlarged view of the partial region R3 of FIG. 7 in accordance with an embodiment of the present disclosure. Taking reference to FIG. 3 and FIG. 8 simultaneously, the indentation 220 is disposed on the surface of the selected region 232 of the adhesive layer 200. The second depth D2 of the indentation 220 is less than the thickness T2 of the electrode 122, which is also less than the first thickness T21 (or called depth) of the portion of the electrode 122 embedded in the adhesive layer 200. The cross-sectional contour of the indentation 220 is a scaled copy of the cross-sectional contour of the electrode 122.

In accordance with an embodiment, when the selected region of the adhesive layer 200 is irradiated by laser beam with certain wavelength (e.g., wavelength 193 nm), the irradiated adhesive layer 200 can be heated and swollen so that the selected semiconductor device is separated from the adhesive layer 200. After that, when laser light is removed, the surface of the adhesive layer 200 can retain the elastically restored indentation 220. According to the aforementioned description, in each of the directions, subject to an external force, when the external force is released and the elastomer restores due to its elastic force, the ratio of the recovered length of the elastomer to the original length of the elastomer is substantially the same. Therefore, the cross-sectional contour of the indentation 220 is similar to the cross-sectional contour of the embedded region of the electrode 122, but the size of the cross-sectional contour of the indentation 220 is less than the size of the cross-sectional contour of the embedded region of the electrode 122.

In order to enable the persons having ordinary skills in the art to implement the present disclosure, the manufacturing method for the semiconductor device arrangement structure of the present disclosure will be further described in detail below.

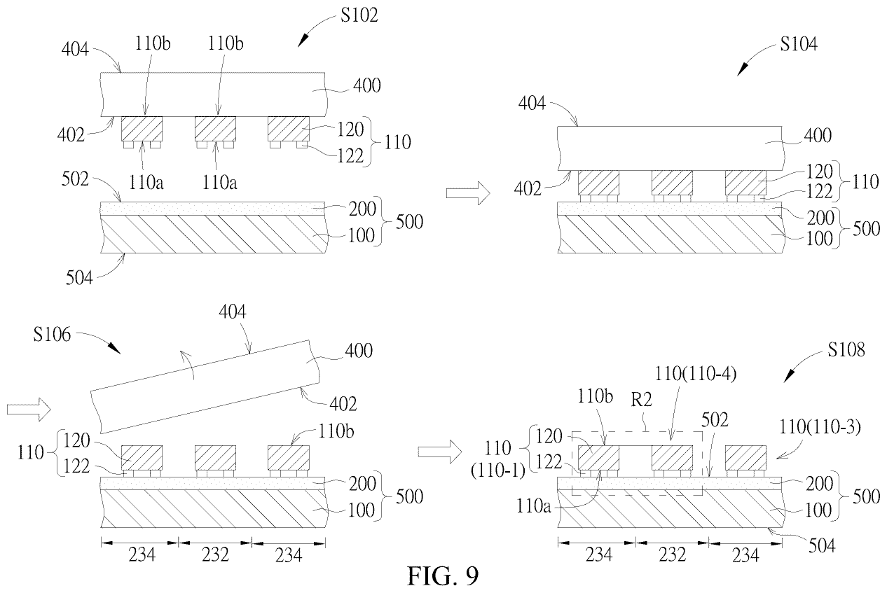

FIG. 9 illustrates cross-sectional views of the semiconductor devices showing that the semiconductor devices are transferred from a first support substrate to a second support substrate in different manufacturing processes in accordance with an embodiment of the present disclosure. As shown in FIG. 9, in the step S102, providing the first support substrate 400 and a plurality of semiconductor devices 110. The semiconductor devices 110 are disposed on the front surface 402 of the first support substrate 400. According to an embodiment, the first support substrate 400 is a growth substrate, and the semiconductor device 110 is grown on the growth substrate. The growth substrate comprises epitaxial material, such as silicon (Si), germanium (Ge), lithium aluminate (LiAlO₂), zinc oxide (ZnO), silicon carbide (SiC), sapphire, gallium nitride (GaN), aluminum nitride (AlN), gallium arsenide (GaAs), and indium phosphide (InP). According to an embodiment, the first support substrate 400 comprises non-epitaxial material and may be non-growth substrate. When the first support substrate 400 comprises non-epitaxial material and may be a non-growth substrate, the adhesive portion such as the adhesive portion 210 shown in FIG. 5 may be included between the back surface 110b of each of the semiconductor devices 110 and the first support substrate 400. The adhesive portion can fix the semiconductor devices 110 to the first support substrate 400, and the adhesive portions each are separated from each other.

Referring to step S102, the semiconductor devices 110 on the first support substrate 400 is then rendered facing the second support substrate 500 so that the electrodes 122 of the semiconductor devices 110 face the adhesive layer 200 of the second support substrate 500. According to an embodiment, the second support substrate has a front surface 502 and a back surface 504 opposite to the front surface 502. The front surface 502 faces the first support substrate 400, while the back surface 504 faces away from the first support substrate 400. The second support substrate 500 comprise non-epitaxial material and may be a non-growth substrate. According to an embodiment, the second support substrate 500 comprises a carrier 100 and an adhesive layer 200. The carrier 100 has sufficient mechanical strength to support the adhesive layer 200. The adhesive layer 200 is a single-layered structure and has sufficient adhesion to fix objects that are pressed to the surface thereof. According to an embodiment, the process of forming the adhesive layer 200 on the second support substrate 500 may be spin coating, which coats liquid state adhesive material on the front surface 102 of the carrier 100, and then performs soft baking and hard baking to form the adhesive layer 200 that has no fluidity and cross-link structure.

In step S104, moving one of the first support substrate 400 and the second support substrate 500 to make the semiconductor devices 110 contact the second support substrate 500 and fixed to the adhesive layer 200. According to an embodiment, pressing process, which may be simultaneously combined with heating process, may be performed for fixing the semiconductor devices 110 to the adhesive layer 200 on the second support substrate 500. A portion of the electrodes 122 can be embedded into the adhesive layer 200 with a depth ranged from 0.02 μm to 0.5 μm. When step S104 is performed, the electrodes 122 exert pressure toward the adhesive layer 200. If the adhesive layer 200 is elastomer, it can be elastically deformed subject to external force to make the electrodes 122 conformally embedded into the adhesive layer 200, thus alleviating the pressure from the electrodes 122.

In step S104 and step S106, a separation process is performed to make the first support substrate 400 separated from the semiconductor devices 110 to expose the back surface 110b of the semiconductor devices 110. According to an embodiment, when the first support substrate 400 is a growth substrate, laser lift-off process may be used for irradiating laser light from the back surface 404 of the first support substrate 400 to the front surface 402 to debond the semiconductor materials, e.g., gallium nitride, aluminum nitride, aluminum gallium nitride, or other compound semiconductor materials, between the semiconductor device 110 and the first support substrate 400. In addition, when the first support substrate 400 is a non-growth substrate, laser lift-off process may be also used for irradiating laser light from the back surface 404 of the first support substrate 400 to the front surface 402 to debond or vaporize the adhesive portion between the semiconductor device 110 and the first support substrate 400. When step S106 is finished, partial semiconductor devices 110, e.g., the first semiconductor devices 110-1 and the third semiconductor device 110-3, can be attached to the unselected region 234 of the adhesive layer 200, while other semiconductor devices 110, e.g., the fourth semiconductor device 110-4, can be attached to the selected region 232 of the adhesive layer 200.

Next, taking reference to step S108, the first support substrate 400 is removed. When the first support substrate 400 is the growth substrate, the cleaning process may be performed to the semiconductor devices 110 to remove the semiconductor residue or metallic residue, e.g., particles containing gallium, on the back surface 110b of the semiconductor devices 110, thus preventing the semiconductor devices 110 from impacting light emitting efficiency caused by low light transmittance residues. According to an embodiment, the back surface 110b of the semiconductor device 110 may be covered by the adhesive portion 210 to present a structure similar to the one shown in FIG. 5.

By means of performing the step S106 through step S108 shown in FIG. 9, the plural semiconductor devices 110 can be transferred from the first support substrate 400 to the second support substrate 500. The plural semiconductor devices 110 are disposed on the second support substrate 500 and are separated from each other. According to an embodiment, the arrangement of the semiconductor devices 110 on the first support substrate 400 is similar to the arrangement of the semiconductor devices 110 on the second support substrate 500. According to an embodiment, the structure of the partial region R3 may be similar to the structure of the partial region R2 shown from FIG. 3 through FIG. 5.

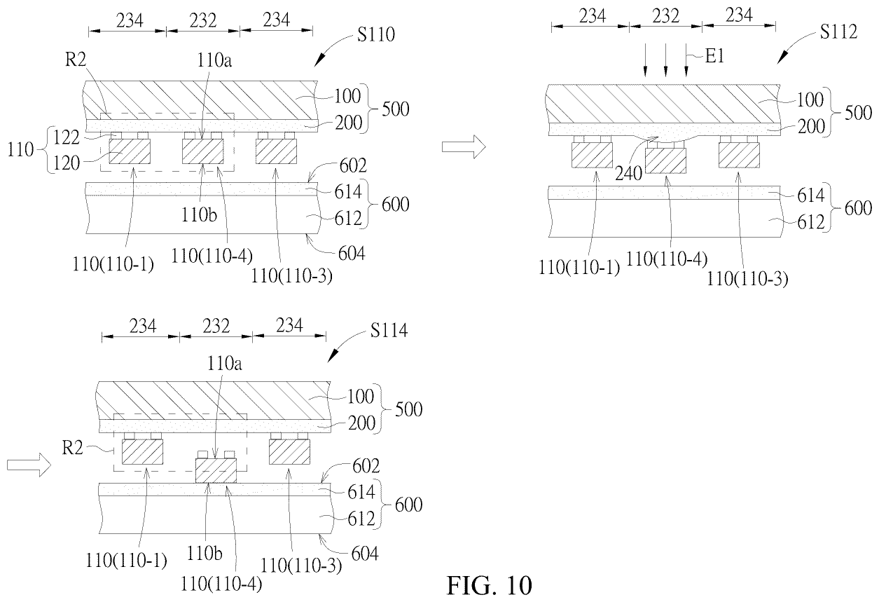

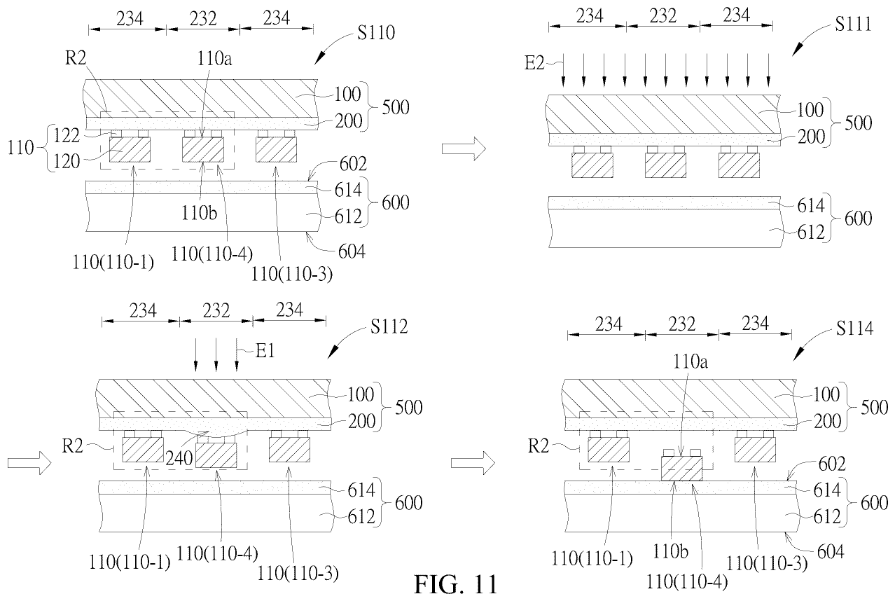

After finishing the arrangement structure shown in step S108, the selected semiconductor devices 110 on the second support substrate 500 may be optionally transferred to other support substrate (or called target substrate) for binning the semiconductor devices 110 in accordance with its similar or the same electric specification or optical specification. The process is illustrated in FIG. 10.

FIG. 10 illustrates cross-sectional views of the semiconductor devices showing that the semiconductor devices are transferred from the second support substrate to a third support substrate in different manufacturing process in accordance with an embodiment of the present disclosure. In step S110, rendering the semiconductor devices 110 on the carrier 100 facing the third support substrate 600 (or called target substrate). According to an embodiment, the third support substrate 600 has a front surface 602 and a back surface 604 opposite to the front surface 602. The front surface 602 faces the carrier 100, while the back surface 604 faces away from the carrier 100. According to an embodiment, the third support substrate 600 comprises a carrier 612 and an attachment layer 614. The carrier 612 comprises non-epitaxial material and may be a non-growth substrate, which has sufficient mechanical strength to support the attachment layer 614. The attachment layer 614 has sufficient adhesion to fix objects that are pressed to the surface thereof. The material of the attachment layer 614 may be the same or different from the material of the adhesive layer 200 shown in FIG. 9, depending on actual needs.

Next, in step S112, under the condition that the semiconductor devices 110 not contacting the surface of the third support substrate 600, energizing the selected region 232 of the adhesive layer 200 via stimulus E1, so that the volume of the selected region 232 rapidly swells to reduce the attachment force between the fourth semiconductor device 110-4 (or called selected semiconductor device) and the adhesive layer 200. In addition, during the rapid swelling of the selected region 232 of the adhesive layer 200, pushing force may be generated to the fourth semiconductor device 100-4 as well. According to an embodiment, the aforementioned “stimulus” may be, e.g., light source or heat source, and the aforementioned “energizing” means irradiating the adhesive layer 200 via the stimulus E1 to render the volume of the irradiated region of the adhesive layer 200 swelling.

According to an embodiment, in step S112, the stimulus E1 is a laser beam with certain wavelength (e.g., wavelength 193 nm). By means of irradiating the aforementioned laser beam to the selected region 232 of the adhesive layer 200, enabling the irradiated selected region 232 being heated and swollen, e.g., swell 10% to 30% in the longitudinal direction. Such swelling can reduce the volume of the recess section on the surface of the selected region to reduce the contact area between the electrodes 122 of the fourth semiconductor device 110-4 and the adhesive layer 200. When the contact area between the electrodes 122 and the adhesive layer 200 is reduced, the attachment force between the electrodes 122 and the adhesive layer 200 is thus lowered. When the fourth semiconductor device 110-4 is subjected to an external force, such as gravity force, then it can be separated from the selected region 232.

In step S112 and step S114, the irradiated adhesive layer 200 can be rapidly heated and swollen within very short time period (e.g., less than 2 seconds) to generate pushing force, e.g., 25 gram-force, toward the fourth semiconductor device 110-4 attached in the selected region 232 to enable the fourth semiconductor device 110-4 to be separated from the selected region 232 of the adhesive layer 200 and transferred to the front surface 602 of the third support substrate 600. It is noted that the value of the aforementioned pushing force value is merely exemplified, the actual value may differ in accordance with laser energy and the material of the adhesive layer 200, thus the pushing force value may be further adjusted in accordance with actual needs. After transferring the fourth semiconductor device 100-4 to the surface of the third support substrate 600, the structure of the partial region R2 may be similar to the structure of the partial region R3 shown in FIG. 8. At this time, the surface of the selected region 232 of the adhesive layer 200 may comprise similar indentation 220 shown in FIG. 8. Compared to that, due to the unselected region 234 being not energized, the first semiconductor device 100-1 and the third semiconductor device 100-3 can remain to be attached to the unselected region 234 of the adhesive layer 200 and are not transferred to the front surface 602 of the third support substrate 600.

Since the adhesive layer 200 is a single-layered elastomer, when the temperature of the selected region 232 rises, it is easily deformed accordingly, making the inner portion of the selected region 232 less likely to cause delamination or rupture, and no chamber is generated between the selected region 232 and the carrier 100. Therefore, even performing the aforementioned energizing process, the selected region 232 can be remained to be attached to the carrier 100, preventing pollution caused by the rupture or the detachment of the adhesive layer 200.

According to an embodiment, in the subsequent process, other semiconductor devices 110 (e.g., the first semiconductor device 110-1 and the third semiconductor device 110-3) may be continuously transferred from the second support substrate 500 to other support substrate or target substrate, and the transferring process may be repeated until all of the semiconductor device 110 on the second support substrate 500 are transferred to the selected the same or different support substrate (or target substrate).

According to an embodiment, the adhesive portion (e.g., the adhesive portion 210 shown in FIG. 5) may be disposed on the back surface 110b of each of the semiconductor device 110 to make the adhesive portion 210 disposed between each of the semiconductor device 110 and the third support substrate 600 and attached to the surface of the attachment layer 614. Due to the electrodes 122 being not covered by the attached adhesive portion 210, even they are not removed, the electric performance of the semiconductor device 110 is not impacted.

FIG. 11 illustrates cross-sectional views of the semiconductor devices showing that the semiconductor devices are transferred from the second support substrate to a third support substrate in different manufacturing processes in accordance with another embodiment of the present disclosure. The manufacturing processes shown in FIG. 11 are similar to the manufacturing processes shown in FIG. 10. The primary difference is that the adhesive layer 200 is light debonding glue, and between performing step S110 and step S112, a step S111 may be additionally performed to irradiate light source E2 (e.g., UV light) to the overall adhesive layer 200 (comprising the selected region 232 and the unselected region 234) to reduce the overall adhesion of the adhesive layer 200, enabling the fourth semiconductor device 110-4 on the selected region 232 being easily transferred to the third support substrate 600 in the subsequent step S112. According to an embodiment, the adhesive layer 200 is an UV light debonding glue. The UV light debonding glue may comprise acrylic acid-based block copolymer, such as a methyl methacrylate-acrylate-methyl methacrylate (MAM) block copolymer. The main chain of such block copolymer comprises cross-linkable functional group. When the UV light debonding glue is irradiated by UV light, a cross-link reaction occurs between the adjacent cross-linkable functional group, enhancing the Young's modulus of the UV light debonding glue and reducing the adhesion of the UV light debonding glue.

Although some embodiments of the present disclosure and their advantages have been described in detail, it should be understood that various changes, substitutions and alterations can be made herein without departing from the spirit and scope of the disclosure as defined by the appended claims.

What is claimed is:

1. A semiconductor device arrangement structure, comprising:
a carrier;
a plurality of semiconductor devices separately disposed on the carrier, the plurality of semiconductor devices each comprising an electrode, the electrode each comprising a contour and a thickness;
an adhesive layer disposed between the carrier and the plurality of semiconductor devices, the plurality of semiconductor devices attached to the adhesive layer, wherein the adhesive layer is a single-layered structure which is continuously distributed and comprises a plurality of unselected regions and a selected region, the plurality of unselected regions are covered by the plurality of semiconductor devices one-on-one respectively, and the selected region is not covered by one of the plurality of semiconductor devices and has a surface; and
an indentation disposed on the surface of the selected region and comprising a depth, and in a cross-sectional view, the indentation having a contour which is a scaled copy of the contour of the electrode of one of the plurality of semiconductor devices, and the depth of the indentation is less than the thickness of the electrode of the aforementioned one of the plurality of semiconductor devices.

2. The semiconductor device arrangement structure as claimed in claim 1, wherein the plurality of the semiconductor devices comprises a first semiconductor device and a second semiconductor device, each of the first semiconductor device and the second semiconductor device comprises a width respectively, the first semiconductor device is adjacent to the second semiconductor device, a shortest distance defined between the first semiconductor device and the second semiconductor device is less than the width of each of the first semiconductor device and the second semiconductor device and greater than one fifth of the width of each of the first semiconductor device and second semiconductor device.

3. The semiconductor device arrangement structure as claimed in claim 1, wherein a portion of the electrode is embedded in the adhesive layer and the portion of the electrode has a depth ranged from 0.02 μm to 0.5 μm.

4. The semiconductor device arrangement structure as claimed in claim 1, wherein the adhesive layer comprises:
a covered portion, disposed at one of the unselected regions and covered by a corresponding one of the plurality of semiconductor devices, the covered portion comprising a first average thickness; and
an exposed portion, disposed at the aforementioned one of the unselected regions and surrounding the covered portion, the exposed portion exposed from the corresponding one of the plurality of semiconductor devices, and the exposed portion comprising a second average thickness;
wherein a ratio of the first average thickness to the second average thickness is ranged from 0.96 to 1.

5. The semiconductor device arrangement structure as claimed in claim 1, wherein when the unselected region of the adhesive layer is irradiated by a laser light with a wavelength of 193 nm, a volume of the unselected region that is irradiated of the adhesive layer is swollen and a pushing force which is equal to or greater than 25 gram-force is generated toward a corresponding one of the plurality of semiconductor devices.

6. A manufacturing method for semiconductor device arrangement structure, comprising steps of:
providing a carrier, wherein the carrier is provided with an adhesive layer on a surface thereof, and the adhesive layer is a single-layered elastomer;
attaching a semiconductor device to a selected region of the adhesive layer;
providing a target substrate comprising a surface facing the semiconductor device and not contacting the semiconductor device; and
energizing the selected region of the adhesive layer to make the semiconductor device separated from the adhesive layer and transferred to the surface of the target substrate, wherein before energizing the selected region of the adhesive layer, the selected region of the adhesive layer is remained to be attached to the carrier.

7. The manufacturing method for semiconductor device arrangement structure as claimed in claim 6, wherein when the adhesive layer is an UV light debonding glue, before energizing the selected region of the adhesive layer, further comprising a step of:
irradiating UV light to the UV light debonding glue to reduce adhesion of the UV light debonding glue.

8. The manufacturing method for semiconductor device arrangement structure as claimed in claim 6, wherein the semiconductor device comprises an electrode, a portion of the electrode is embedded in the adhesive layer, and the portion of the electrode comprises a depth ranged from 0.02 μm to 0.5 μm.

9. The manufacturing method for semiconductor device arrangement structure as claimed in claim 6, wherein in the step of energizing the selected region of the adhesive layer, laser light is employed to irradiate the selected region of the adhesive layer.

10. The manufacturing method for semiconductor device arrangement structure as claimed in claim 6, further comprising:
before proving the target substrate, attaching another semiconductor device to an unselected region of the adhesive layer; and
after energizing the selected region of the adhesive layer, the aforementioned another one semiconductor device is remained to be attached to the unselected region of the adhesive layer.
